(19) United States
(12) Patent Application Publication
(10) Pub. No.: US 2014/0069694 A1
(43) Pub. Date: Mar. 13, 2014

(54) CIRCUIT BOARD AND METHOD FOR MANUFACTURING THE SAME

(71) Applicant: SAMSUNG ELECTRO-MECHANICS CO., LTD., Suwon (KR)

(72) Inventors: Seong Min CHO, Suwon (KR); Eun Heay Iee, Suwon (KR); Jung Youn Pang, Suwon (KR); Shimoji Teruaki, Suwon (KR); Chi Seong Kim, Suwon (KR)

(73) Assignee: Samsung Electro-Mechanics Co., Ltd., Suwon (KR)

(21) Appl. No.: 13/827,269

(22) Filed: Mar. 14, 2013

(30) Foreign Application Priority Data
Sep. 10, 2012 (KR) 10-2012-0099857

(51) Int. Cl. H05K 3/18; H05K 1/02

(52) U.S. Cl. CPC H05K 3/182; H05K 1/0298
USPC 174/251; 216/18

(57) ABSTRACT

A circuit board includes a circuit pattern formed on a substrate, a first solder resist layer formed on the circuit pattern, an electroless plating layer formed on the circuit pattern on which the first solder resist layer is opened, and a second solder resist layer formed on the first solder resist layer, and a method for manufacturing the same. According to certain embodiments, it is possible to cover a portion which has vulnerable plating quality due to solder resist residue or insufficient wetting around an edge of an existing solder resist layer by including an additional solder resist layer on a surface-treated plating layer. Further, it is possible to protect an undercut portion under the solder resist layer by forming the additional solder resist layer.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2012-0099857, entitled filed Sep. 10, 2012, which is hereby incorporated by reference in its entirety into this application.

### BACKGROUND OF THE INVENTION

1. Field of the Invention

The present invention relates to a circuit board and a method for manufacturing the same.

2. Description of the Related Art

There are several surface finish methods for a substrate. First, plating. Second, organic solderability preservative (OSP). Third, a combination of plating and OSP. These several surface finish methods are selected according to their purpose or cost, reliability, and customer preference and applied to manufacture of the substrate.

The plating methods include electroless gold plating surface finishes such as electroless nickel immersion gold (ENIG) and electroless nickel electroless palladium immersion gold (ENEPIG) and electrolytic gold plating such as electrolytic Ni/Au. Among them, the electroless plating is preferred.

In the past, one kind of surface finish method was mainly applied to all of top/bottom/sides of a substrate, but from early to mid-2000s, a selective surface finish technology, which applies both of electrolytic gold plating surface finish and OSP, began to be widely applied. However, an electroless gold plating method, which has a problem of elution of a dry film from a plating solution, can't easily apply selective surface finish compared to the electrolytic gold plating method which can easily perform the selective surface finish using a dry film etc.

In recent times, according to the development of materials with improved elution properties and technologies such as LDA, development of selective surface finish technologies has been actively performed in the electroless gold plating method.

An OSP treatment is performed for the selective surface finish in the electroless gold plating method. A typical process configuration of the OSP is input->degreasing (pickling)->soft etching->OSP pretreatment->OSP treatment-> discharge. In the above process, the degreasing (pickling) and etching processes mainly use many acid components (for example, sulfuric acid).

However, since a thickness of Pd or Au of ENEPIG or thin Ni ENEPIG which is electroless gold plating is very small, it is not easy for a plated surface to have perfect acid-resistance under an acidic atmosphere. Therefore, corrosion of the gold-plated surface occurs in the pickling and etching processes of the OSP treatment.

A conventional method for manufacturing a substrate is not concerned about a method of forming a circuit (tenting, MSAP, AMSAP, SAP, etc), and a typical structure after applying, exposing, and developing solder resist (SR) is as in FIG. 1.

FIG. 1 shows a typical form of a structure in which SR 30 is formed on a surface mount device (SMD) type copper pad 20, and surface finish plating is performed on the structure of this form. The surface finish is described by taking electroless gold plating as an example.

FIGS. 2 and 3 show structures of ENEPIG (nickel 40, palladium 50, gold 60) and thin Ni ENEPIG (nickel 40, palladium 50, gold 60), which are electroless gold plating surface finishes, on the SMD type copper pad 20 on which the SMD type solder resist of FIG. 1 is opened, respectively.

Since the electroless plating is characterized by forming a plating layer only by a chemical reaction unlike electrolytic plating, constitution and structure of the plating layer are different from those of the electrolytic plating and there is limit to a deposition rate of a plating thickness or a plating thickness that can be formed.

Further, FIG. 4 shows surface shapes before selective OSP treatment (4a) and surface shapes of ENEPIG (FIG. 4b) and thin Ni ENEPIG (FIG. 4c) after OSP treatment, after ENEPIG or thin Ni ENEPIG plating. Referring to this, in the ENEPIG and thin Ni ENEPIG, corrosion in the direction of an SR edge is observed after the OSP. This phenomenon shows that plating quality (coverage) in the direction of the SR edge is not good. That is, it can be expected that plating protection characteristics are not good compared to a center portion of the copper pad due to deterioration of reactivity caused by SR residue remaining on the SR edge or poor flow of a plating solution on the SR edge.

If an OSP pretreatment process is performed in this state, corrosion occurs severely due to a reaction such as galvanic corrosion in the degreasing or pickling and soft etching processes consisting of an acid component.

Further, another additional problem is that an undercut problem particularly on the SR edge becomes more severe in the surface finish method which consists of only a thin film such as thin Ni ENEPIG. In the conventional method such as ENIG or ENEPIG, since a thickness of Ni is at least greater than 3 μm, generally 5 to 7 μm, although an undercut occurs, since the undercut is filled by Ni plating, it is not a big problem.

However, the methods such as thin Ni ENEPIG or EPIG in which a total thickness of a plating layer is less than 1 μm, this undercut portion may become a quality vulnerable portion. That is, since the plating quality of the undercut portion can be only bad, when an acid treatment using OSP is performed on this portion again, severe corrosion occurs as in FIG. 5.

### RELATED ART DOCUMENT

### Patent Document

Patent Document 1: Korean Patent Laid-Open No. 2012-46495

### SUMMARY OF THE INVENTION

The present invention has been invented in order to overcome the conventional problems and it is, therefore, an object of the present invention to provide a circuit board capable of overcoming the problems related to corrosion of a plating layer in conventional selective surface treatment using electroless gold plating and OSP.

Further, it is another object of the present invention to provide a circuit board capable of overcoming a plating vulnerable portion of an edge portion of a solder resist layer and an undercut under the solder resist layer.

Additionally, it is still another object of the present invention to provide a method for manufacturing a circuit board that can overcome the conventional technology as above.

In accordance with one aspect of the present invention to achieve the object, there is provided a circuit board including: a circuit pattern formed on a substrate; a first solder resist layer formed on the circuit pattern; an electroless plating layer formed on the circuit pattern on which the first solder resist layer is opened; and a second solder resist layer formed on the first solder resist layer.

It is preferred that the second solder resist layer extends to a portion of the electroless plating layer including the region in which the first solder resist layer is formed.

The electroless plating layer may be formed of at least one layer selected from a nickel (Ni) layer, a palladium (Pd) layer, and a gold (Au) layer.

It is preferred that the circuit pattern uses copper (Cu).

In accordance with another aspect of the present invention to achieve the object, there is provided a method for manufacturing a circuit board including the steps of: forming a circuit pattern on a substrate; applying a first solder resist layer on the circuit pattern; etching the first solder resist layer to open the circuit pattern; forming an electroless plating layer by surface-treating the circuit pattern; and forming a second solder resist layer on the surface-treated first solder resist layer.

It is preferred that the second solder resist layer extends to a portion of the electroless plating layer including the region in which the first solder resist layer is formed.

The electroless plating layer may be formed by at least one method selected from the group consisting of electroless nickel immersion gold (ENIG), electroless nickel electroless palladium immersion gold (ENEPIG), electroless palladium immersion gold (EPIG), thin Ni ENEPIG, and direct immersion gold (DIG).

A nickel (Ni) layer of the electroless plating layer may have a thickness of 2 to 9 μm in case of ENIG and ENEPIG and 0.1 to 1.0 μm in case of thin Ni ENEPIG.

In accordance with still another aspect of the present invention to achieve the object, there is provided a circuit board including: a circuit pattern formed on a substrate; an electroless plating layer formed on the circuit pattern; and a solder resist layer formed on the electroless plating layer.

It is preferred that the electroless plating layer is formed on top and both sides of the circuit pattern in the same shape as the circuit pattern.

The electroless plating layer may be formed of at least one layer selected from a nickel (Ni) layer, a palladium (Pd) layer, and a gold (Au) layer.

It is preferred that the circuit pattern uses copper (Cu).

In accordance with still another aspect of the present invention to achieve the object, there is provided a method for manufacturing a circuit board including the steps of: forming a circuit pattern on a substrate; forming an electroless plating layer by surface-treating the circuit pattern; and forming a solder resist layer on the electroless plating layer.

The electroless plating layer may be formed by at least one method selected from the group consisting of electroless nickel immersion gold (ENIG), electroless nickel electroless palladium immersion gold (ENEPIG), electroless palladium immersion gold (EPIG), thin Ni ENEPIG, and direct immersion gold (DIG).

A nickel (Ni) layer of the electroless plating layer may have a thickness of 2 to 9 μm in case of ENIG and ENEPIG and 0.1 to 1.0 μm in case of thin Ni ENEPIG.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 shows a typical structure in which SR is formed after a copper (Cu) circuit is formed;

FIG. 2 shows a structure in which Ni/Pd/Au layers are formed by applying ENEPIG plating to a copper (Cu) circuit;

FIG. 3 shows a thin Ni ENEPIG structure in which a thickness of Ni is very small in the ENEPIG plating of FIG. 2;

FIGS. 4a to 4c show surface shapes (a) before OSP treatment, (b) ENEPIG after OSP treatment, and (c) thin Ni ENEPIG after OSP treatment;

FIG. 5 shows various shapes of corrosion generated in an undercut under an SR edge;

FIGS. 6 and 7 show a structure of a circuit board in accordance with an embodiment of the present invention;

FIGS. 8 and 9 show effects of the circuit board having the structure of FIGS. 6 and 7;

FIG. 10 shows a structure of a circuit board in accordance with another embodiment of the present invention; and

FIG. 11 shows effects of the circuit board having the structure of FIG. 10.

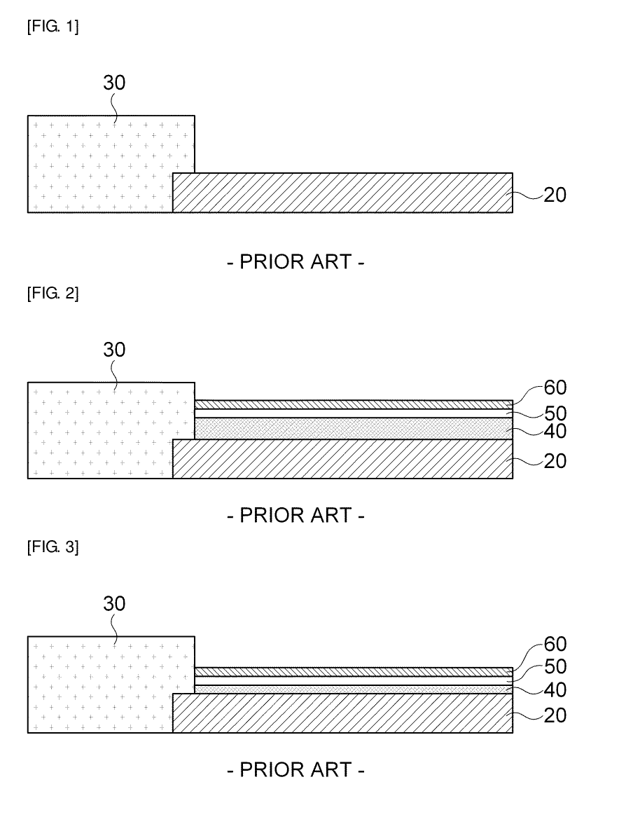

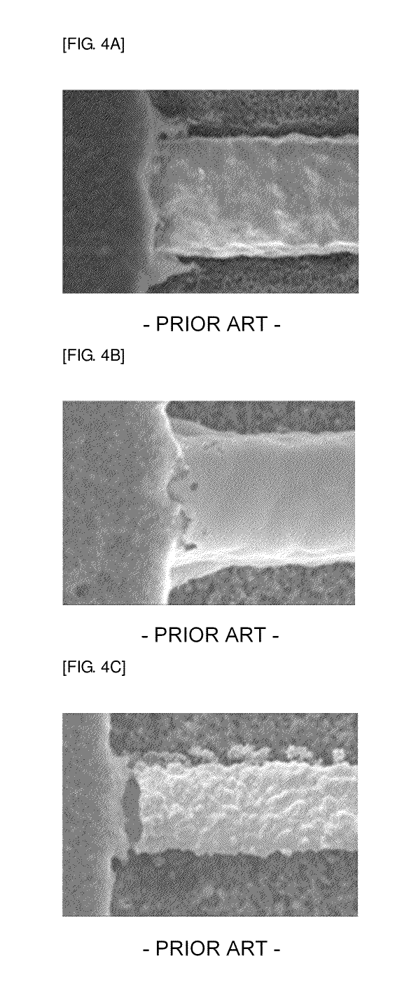

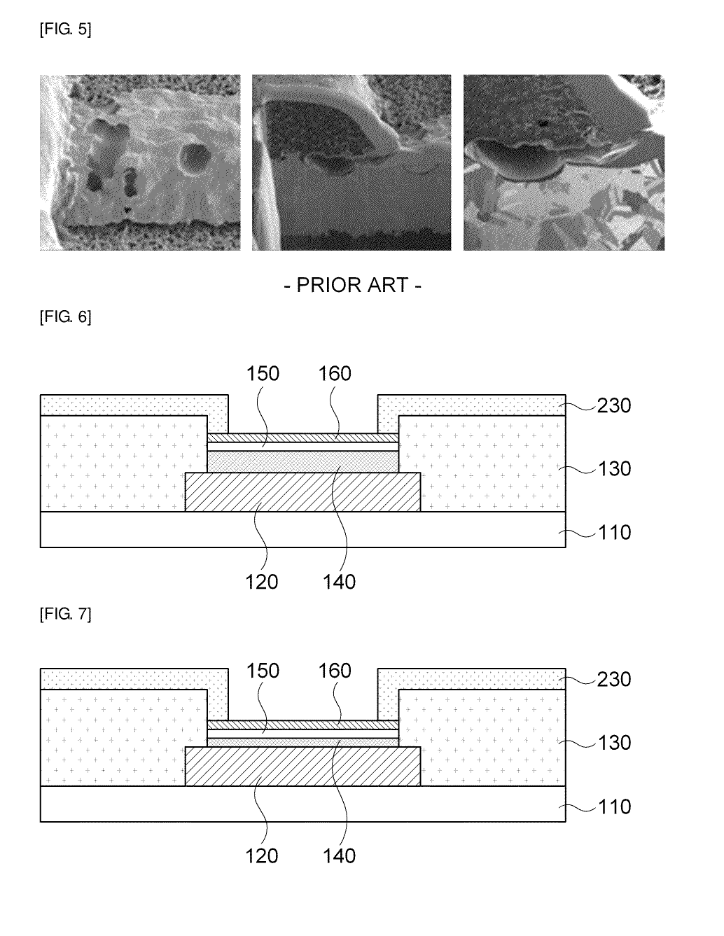

### DETAILED DESCRIPTION OF THE PREFERABLE EMBODIMENTS

Hereinafter, the present invention will be described in detail with reference to the accompanying drawings.

Terms used herein are provided to explain specific embodiments, not limiting the present invention. Throughout this specification, the singular form includes the plural form unless the context clearly indicates otherwise. Further, terms “comprises” and/or “comprising” used herein specify the existence of described shapes, numbers, steps, operations, members, elements, and/or groups thereof, but do not preclude the existence or addition of one or more other shapes, numbers, operations, members, elements, and/or groups thereof.

The present invention relates to a circuit board having a structure that can overcome defects such as corrosion or undercut of conventional solder resist in surface-treating a circuit board using electroless gold plating and organic solderability preservative treatment, and a method for manufacturing the same.

As shown in FIG. 6, a circuit board in accordance with an embodiment of the present invention includes a circuit pattern 120 formed on a substrate 110, a first solder resist layer 130 formed on the circuit pattern 120, an electroless plating layer 140, 150, and 160 formed on the circuit pattern 120 on which the first solder resist layer 130 is opened, and a second solder resist layer 230 formed on the first solder resist layer 130.

The most obvious and simple way to improve defects in the prior art is to seek a way to maintain plating quality (coverage) of the same level as the center even on the edge side of the solder resist layer during plating. If the plating quality is not deteriorated compared to the center, it is possible to prevent corrosion on the edge side.

However, improvement of the plating quality on the edge side of the solder resist layer is never easy or can be done in a short time. Therefore, the present invention aims to complement this defect by changing a structure of the product as the second best.

That is, as shown in FIG. 6, an embodiment of the present invention is characterized by further including the additional second solder resist layer. The second solder resist layer 230 is formed by applying plating layers 140, 150, and 160 using ENEPIG or thin Ni ENEPIG to cover a wider range of the copper circuit pattern 120 than the first solder resist layer 130 formed in the early. That is, it is preferred that the second solder resist layer 230 extends to a portion of the electroless plating layer 140, 150, and 160 including the region in which the first solder resist layer 130 is formed.

Therefore, the second solder resist layer 230, which additionally covers the wider range of the copper circuit pattern 120 than the first solder resist layer 130, can cover the entire undercut portion which has poor plating quality during plating and is generated by many etching processes after the solder resist process.

A method for manufacturing a circuit board in accordance with an embodiment of the present invention having a structure of FIG. 6 includes the steps of forming a circuit pattern on a substrate, applying a first solder resist layer on the circuit pattern, etching the first solder resist layer to open the circuit pattern, forming an electroless plating layer by surface-treating the circuit pattern, and applying a second solder resist layer on the surface-treated first solder resist layer.

Like a typical circuit board, the circuit pattern is formed on the substrate, and the circuit pattern may be most preferably copper. Next, the first solder resist layer is formed on the circuit pattern. A solder resist composition for forming the first solder resist layer is not particularly limited, and any composition used in the typical circuit board can be used.

Next, in order to perform surface treatment on the circuit pattern, the first solder resist layer is etched to open the circuit pattern portion. A method of etching the first solder resist layer is not particularly limited.

The opened circuit pattern is surface-treated by electroless plating to obtain the electroless plating layer formed by sequentially stacking a nickel (Ni) layer 140, a palladium (Pd) layer 150, and a gold (Au) layer 160. However, the electroless plating layer in accordance with the present invention is not necessarily stacked in the same order as above and may be formed of at least one layer selected from the nickel layer, the palladium layer, and the gold layer or by selecting the layer according to the need. The electroless plating layer may be formed by at least one method selected from the group consisting of electroless nickel immersion gold (ENIG), electroless nickel electroless palladium immersion gold (ENEPIG), electroless palladium immersion gold (EPIG), thin Ni ENEPIG, and direct immersion gold (DIG).

Therefore, the electroless plating layer can be applied to a structure of FIG. 7 having a thin nickel layer as well as the structure of FIG. 6 having the relatively thick nickel layer 140. It is preferred that the nickel (Ni) layer of the electroless plating layer has a thickness of 2 to 9 μm in case of ENIG and ENEPIG and 0.1 to 1.0 μm in case of thin Ni ENEPIG.

Finally, the second solder resist layer 230 is formed on the surface-treated first solder resist layer 130. The second solder resist layer 230 is formed in the region including an edge portion of the first solder resist layer 130 to cover the edge portion of the first solder resist layer 130 which has vulnerable plating quality. That is, it is preferred that the second solder resist layer 230 extends to a portion of the electroless plating layer 140, 150, and 160 including the region in which the first solder resist layer 130 is formed.

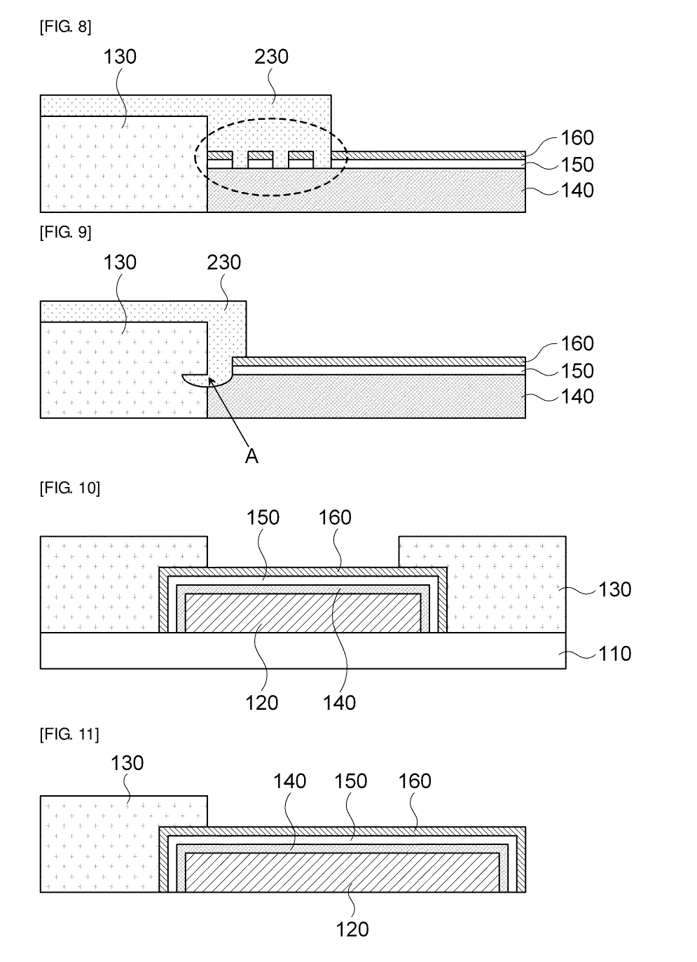

Therefore, as in FIG. 8, it is possible to cover the portion which has vulnerable plating quality due to solder resist residue or insufficient wetting around the edge of the first solder resist layer 130 through the application of the additional second solder resist layer 230.

In addition, as in FIG. 9, it is expected to protect an undercut portion A under the first solder resist layer 130 by applying the additional second solder resist layer 230.

Meanwhile, in the present invention, as another method to overcome the problems of the prior art by changing the structure of the product, contrary to a typical method of performing surface treatment plating after forming a solder resist layer, it is possible to prevent deterioration of quality of surface treatment plating due to solder resist residue or insufficient wetting from the beginning by performing surface treatment plating first and then forming a solder resist layer.

Therefore, as shown in FIG. 10, a circuit board in accordance with another embodiment of the present invention includes a circuit pattern 120 formed on a substrate 110, an electroless plating layer 140, 150, and 160 formed on the circuit pattern 120, and a solder resist layer 130 formed on the electroless plating layer.

It is preferred that the electroless plating layer 140, 150, and 160 is formed on top and both sides of the circuit pattern 120 in the same shape as the circuit pattern 120.

Further, it is preferred that a nickel (Ni) layer of the electroless plating layer has a thickness of 2 to 9 μm in case of ENIG and ENEPIG and 0.1 to 1.0 μm in case of thin Ni ENEPIG.

A method for manufacturing a circuit board in accordance with an embodiment of the present invention having a structure of FIG. 10 includes the steps of forming a circuit pattern on a substrate, forming an electroless plating layer by surface-treating the circuit pattern, and forming a solder resist layer on the electroless plating layer.

Like a typical circuit board, the circuit pattern 120 is formed on the substrate 110, and the circuit pattern 120 may be most preferably copper.

Next, the circuit pattern 120 is surface-treated by electroless plating to form the electroless plating layer formed by sequentially stacking a nickel (Ni) layer 140, a palladium (Pd) layer 150, and a gold (Au) layer 160. However, the electroless plating layer in accordance with the present invention is not necessarily stacked in the same order as above and may be formed of at least one layer selected from the nickel layer, the palladium layer, and the gold layer or by selecting the layer according to the need.

According to the embodiment, since the circuit pattern 120 is surface-treated first, the electroless plating layer 140, 150, and 160 is formed in the same shape as the circuit pattern 120. That is, the electroless plating layer 140, 150, and 160 is formed on top and both sides of the circuit pattern 120.

The electroless plating layer may be formed by at least one method selected from the group consisting of electroless nickel immersion gold (ENIG), electroless nickel electroless palladium immersion gold (ENEPIG), electroless palladium immersion gold (EPIG), thin Ni ENEPIG, and direct immersion gold (DIG).

Finally, the solder resist layer is formed on the electroless plating layer. A solder resist composition for forming the solder resist layer is not particularly limited, and any composition used in the typical circuit board can be used.

In case of having the structure as above, since it is possible to perform surface treatment plating on the copper circuit pattern 120 without any obstacle, it is possible to exhibit uniform plating thickness and plating quality on the entire copper circuit pattern as in FIG. 11.

According to an embodiment of the present invention, it is possible to cover a portion which has vulnerable plating quality due to solder resist residue or insufficient wetting around an edge of an existing solder resist layer by including an additional solder resist layer on a surface-treated plating layer. Further, it is possible to protect an undercut portion under the solder resist layer by forming the additional solder resist layer.

Further, according to another embodiment of the present invention, it is possible to exhibit uniform plating thickness and plating quality on the entire circuit pattern by performing surface treatment first before forming a solder resist layer on the circuit pattern to form a plating layer.

What is claimed is:

1. A circuit board comprising:
a circuit pattern formed on a substrate;
a first solder resist layer formed on the circuit pattern;
an electroless plating layer formed on the circuit pattern on which the first solder resist layer is opened; and
a second solder resist layer formed on the first solder resist layer.

2. The circuit board according to claim 1, wherein the second solder resist layer extends to a portion of the electroless plating layer including the region in which the first solder resist layer is formed.

3. The circuit board according to claim 1, wherein the electroless plating layer is formed of at least one layer selected from a nickel (Ni) layer, a palladium (Pd) layer, and a gold (Au) layer.

4. The circuit board according to claim 1, wherein the circuit pattern uses copper (Cu).

5. A method for manufacturing a circuit board, comprising:
forming a circuit pattern on a substrate;
applying a first solder resist layer on the circuit pattern;
etching the first solder resist layer to open the circuit pattern;
forming an electroless plating layer by surface-treating the circuit pattern; and
forming a second solder resist layer on the surface-treated first solder resist layer.

6. The method for manufacturing a circuit board according to claim 5, wherein the second solder resist layer extends to a portion of the electroless plating layer including the region in which the first solder resist layer is formed.

7. The method for manufacturing a circuit board according to claim 5, wherein the electroless plating layer is formed by at least one method selected from the group consisting of electroless nickel immersion gold (ENIG), electroless nickel electroless palladium immersion gold (ENEPIG), electroless palladium immersion gold (EPIG), thin Ni ENEPIG, and direct immersion gold (DIG).

8. The method for manufacturing a circuit board according to claim 7, wherein a nickel (Ni) layer of the electroless plating layer has a thickness of 2 to 9 μm in case of ENIG and ENEPIG and 0.1 to 1.0 μm in case of thin Ni ENEPIG.

9. A circuit board comprising:
a circuit pattern formed on a substrate;
an electroless plating layer formed on the circuit pattern; and
a solder resist layer formed on the electroless plating layer.

10. The circuit board according to claim 9, wherein the electroless plating layer is formed on top and both sides of the circuit pattern in the same shape as the circuit pattern.

11. The circuit board according to claim 9, wherein the electroless plating layer is formed of at least one layer selected from a nickel (Ni) layer, a palladium (Pd) layer, and a gold (Au) layer.

12. The circuit board according to claim 9, wherein the circuit pattern uses copper (Cu).

13. A method for manufacturing a circuit board, comprising:
forming a circuit pattern on a substrate;
forming an electroless plating layer by surface-treating the circuit pattern; and
forming a solder resist layer on the electroless plating layer.

14. The method for manufacturing a circuit board according to claim 13, wherein the electroless plating layer is formed by at least one method selected from the group consisting of electroless nickel immersion gold (ENIG), electroless nickel electroless palladium immersion gold (ENEPIG), electroless palladium immersion gold (EPIG), thin Ni ENEPIG, and direct immersion gold (DIG).

15. The method for manufacturing a circuit board according to claim 14, wherein a nickel (Ni) layer of the electroless plating layer has a thickness of 2 to 9 μm in case of ENIG and ENEPIG and 0.1 to 1.0 μm in case of thin Ni ENEPIG.
